(19) United States
(12) Patent Application Publication
(10) Pub. No.: US 2019/0316003 A1
(43) Pub. Date: Oct. 17, 2019

(54) SLURRY COMPOSITION FOR POLISHING HIGH STEPPED REGION

(71) Applicant: KCTECH CO., LTD., Gyeonggi-do (KR)

(72) Inventors: Jung Yoon KIM, Gyeonggi-do (KR); Jun Ha HWANG, Gyeonggi-do (KR); Sun Kyoung KIM, Gyeonggi-do (KR); Kwang Soo PARK, Gyeonggi-do (KR)

(73) Assignee: KCTECH CO., LTD., Gyeonggi-do (KR)

(21) Appl. No.: 16/302,604

(22) PCT Filed: Apr. 14, 2017
(86) PCT No.: PCT/KR2017/004041

§ 371 Date: Nov. 16, 2018

(30) Foreign Application Priority Data
May 16, 2016 (KR) 10-2016-0059622

(51) Int. Cl. C09G 1/02; C09K 13/00; C09K 3/14

(52) U.S. Cl. CPC C09G 1/02; C09K 13/00; H01L 21/31053; C09K 3/1463; C09K 3/1409

(57) ABSTRACT

The present invention relates to a slurry composition for polishing a high stepped region. The slurry composition for polishing a high stepped region according to an embodiment of the present invention comprises: a polishing liquid containing metal oxide abrasive particles dispersed by positive charges; and an additive liquid containing a polymer comprising at least one element capable of being activated as a positive charge, wherein the polishing selection ratio of the stepped region removal rate in an oxide film pattern wafer having convex portions and concave portions and the stepped region removal rate in an oxide film flat wafer is at least 5:1.

### TECHNICAL FIELD

Example embodiments relate to a slurry composition for polishing a high-step height region.

### BACKGROUND ART

With diversification and high integration of semiconductor devices, techniques to form finer patterns are being used, and accordingly surface structures of semiconductor devices become more complicated and a step height of surface films becomes greater. In manufacturing of semiconductor devices, a chemical mechanical polishing (CMP) process is used as a planarization technique to remove a step height region of a specific film formed on a substrate. The CMP process is, for example, a process for removing an insulating film excessively formed for layer insulation, and is widely used to planarize an interlayer dielectric (ILD) and an insulating film for shallow trench isolation (STI) to insulate chips from each other, and used to form a metal conductive film, for example, a wiring, a contact plug or a via contact. In the CMP process, a polishing speed, a degree of planarization of a polished surface and an incidence of scratches are important, and determined based on, for example, CMP conditions, types of slurries or types of polishing pads. As a degree of integration increases and a standard of a process becomes stricter, a need to rapidly planarize an insulating film having a very high-step height becomes important. An area with a small pattern and a high density is locally planarized, and a wide area with a large pattern reflects an initial step height without a change. Since step height regions are not completely removed in a convex portion and a concave portion on a pattern wafer, a step height region remains even after polishing to reduce a planarization efficiency. When a slurry is prepared and used by mixing a slurry dispersed as a negative charge and an anionic polymer additive to remove a step height region, the anionic polymer additive is agglomerated with a slurry dispersed as a positive charge, which leads to an increase in scratches and defects. Also, since the anionic polymer additive rapidly reduces a polishing speed of the slurry dispersed as the positive charge, a step height removal performance is reduced and there is a limit in increasing the polishing speed.

### DISCLOSURE OF INVENTION

### Technical Subject

The present disclosure is to solve the foregoing problems, and an aspect of the present disclosure is to provide a slurry composition for polishing a high-step height region which has an automatic polishing stop function of quickly polishing a convex portion of a pattern wafer having a high-step height, and planarizing a surface of the pattern wafer, and rapidly reducing a polishing speed after a removal of a step height region to protect the planarized surface.

However, the problems to be solved in the present disclosure are not limited to the foregoing problems, and other problems not mentioned herein would be clearly understood by one of ordinary skill in the art from the following description.

### Technical Solution

According to an aspect, there is provided a slurry composition for polishing a high-step height region including: a polishing liquid containing metal oxide abrasive particles dispersed as positive charges; and an additive liquid containing a polymer including at least one element capable of being activated into a positive charge, wherein a polishing selectivity between a step height removal rate (SHRR) in an oxide film pattern wafer having a convex portion and a concave portion and a blanket wafer removal rate (BWRR) in an oxide film blanket wafer is greater than or equal to “5:1.”

A selectivity between a removal rate of the convex portion and a removal rate of the concave portion in the oxide film pattern wafer may be greater than or equal to “5:1.” The metal oxide abrasive particles may include at least one selected from the group consisting of a metal oxide, a metal oxide coated with an organic material or inorganic material, and the metal oxide in a colloidal phase. The metal oxide may include at least one selected from the group consisting of silica, ceria, zirconia, alumina, titania, barium titania, germania, mangania and magnesia.

The metal oxide abrasive particles may be ceria in a colloidal phase dispersed as positive charges.

The polymer may include at least one nitrogen activated as a positive charge.

The polymer may be in a form of a quaternary ammonium, or a quaternary ammonium salt.

The polymer may include at least one selected from the group consisting of poly(diallyldimethyl ammonium chloride); poly[bis(2-chloroethyl) ether-alt-1,3-bis[3-(dimethylamino)propyl]urea]; ethanol, 2,2′,2″-nitrilotris-, polymer with 1,4-dichloro-2-butene and N,N,N′,N′-tetramethyl-2-butene-1,4-diamine; a hydroxyethyl cellulose dimethyl diallylammonium chloride copolymer; a copolymer of acrylamide and diallyldimethylammonium chloride; a copolymer of acrylamide and quaternized dimethylammoniumethyl methacrylate; a copolymer of acrylic acid and diallyldimethylammonium chloride; an acrylamide-dimethylaminoethyl methacrylate methyl chloride copolymer; quaternized hydroxyethyl cellulose; a copolymer of vinylpyrrolidone and quaternized dimethylaminoethyl methacrylate; a copolymer of vinylpyrrolidone and quaternized vinylimidazole; a copolymer of vinylpyrrolidone and methacrylamidopropyl trimethylammonium; poly(2-methacryloxyethyltrimethylammonium chloride); poly(acrylamide 2-methacryloxyethyltrimethyl ammonium chloride); poly[2-(dimethylamino)ethyl methacrylate) methyl chloride]; poly[(3-acrylamidopropyl) trimethylammonium chloride]; poly[(3-methacrylamidopropyl) trimethylammonium chloride]; poly[oxyethylene(dimethylimino)ethylene (dimethylimino)ethylene dichloride]; a terpolymer of acrylic acid, acrylamide and diallyldimethylammonium chloride; a terpolymer of acrylic acid, methacrylamidopropyl trimethylammonium chloride, and methyl acrylate, a terpolymer of vinylcaprolactam, vinylpyrrolidone, and quaternized vinylimidazole; poly(2-methacryloxyethyl phosphorylcholine-co-n-butyl methacrylate); poly[(dimethylamino)ethyl acrylate benzyl chloride quaternary salt (PDMAEA-BCQ); poly[(dimethylamino)ethyl acrylate methyl chloride quaternary salt (PDMAEA-MCQ); and polymethacrylamidopropyltrimonium chloride.

The polymer including at least one element capable of being activated into a positive charge may be present in an amount of 0.001% by weight (wt %) to 0.1 wt % in the slurry composition.

The slurry composition may further include at least one acidic material selected from the group consisting of picolinic acid, polyacrylic acid, a polyacrylic acid-containing copolymer, polysulfonic acid, carboxylic acid, amino acid, acetic acid, malic acid, malonic acid, maleic acid, oxalic acid, phthalic acid, succinic acid, tartaric acid, citric acid, glutaric acid, glycolic acid, formic acid and lactic acid.

The slurry composition may further include a basic material with a pKa value greater than or equal to “9.”

The basic material may include at least one selected from the group consisting of arginine, ammonium hydroxide (NH₄OH), propylamine, triethylamine, tributylamine, tetramethylamine, tetramethylammonium hydroxide, monoethanolamine, diethanolamine, triethanolamine, 2-amino-2-ethyl-1,3-propanediol, 2-dimethylamino-2-methyl-1-propanol, 1-amino-2-propanol, 1-dimethylamino-2-propanol, 3-dimethylamino-1-propanol, 2-amino-1-propanol, 2-dimethylamino-1-propanol, 2-diethylamino-1-propanol, 2-diethylamino-1-ethanol, 2-ethylamino-1-ethanol, 1-(dimethylamino)2-propanol, N-methyldiethanolamine, N-propyldiethanolamine, N-isopropyldiethanolamine, N-(2-methylpropyl)diethanolamine, N-n-butyldiethanolamine, N-t-butylethanolamine, N-cyclohexyldiethanolamine, 2-(dimethylamino)ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl)ethanolamine, 2-amino-2-methyl-1-propanol, tris(hydroxymethyl)aminomethane, and triisopropanolamine.

The slurry composition may have a pH in a range of 3 to 8.

The slurry composition may further include water. A ratio of the polishing liquid:the water:the additive liquid may be in a range of “1:3 to 10:1 to 8.” EFFECT

According to example embodiments, a slurry composition for polishing a high-step height region may have an effect of increasing a step height removal rate by having a high polishing speed at a convex portion in a pattern wafer, removing a step height region of the pattern wafer, achieving a planarization by rapidly reducing a polishing speed after the step height region is removed, and strengthening a polishing stop function at a low-step height region. Also, a slurry composition including ceria abrasive particles may have an effect of minimizing scratches and defects when a step height region is removed. Thus, a polishing process margin may be excellent and a polishing time may be shortened, thereby increasing a productivity.

### BEST MODE FOR CARRYING OUT THE INVENTION

Hereinafter, example embodiments of the present disclosure will be described in detail with reference to the accompanying drawings. When it is determined detailed description related to a related known function or configuration they may make the purpose of the present disclosure unnecessarily ambiguous in describing the present disclosure, the detailed description will be omitted here. Also, terminologies used herein are defined to appropriately describe the example embodiments and thus may be changed depending on a user, the intent of an operator, or a custom of a field to which the present disclosure pertains. Accordingly, the terminologies must be defined based on the following overall description of this specification. Like reference numerals illustrated in the drawings refer to like constituent elements throughout the specification.

Throughout the whole document, the term “comprises or includes” and/or “comprising or including” specify the presence of stated elements or components, but do not preclude the presence or addition of one or more other elements or components, unless mentioned otherwise.

Hereinafter, a slurry composition for polishing a high-step height region according to example embodiments of the present disclosure will be described in detail with reference to examples and drawings. However, the present disclosure is not limited to the examples and drawings.

According to an example embodiment, a slurry composition for polishing a high-step height region is provided. The slurry composition includes a polishing liquid containing metal oxide abrasive particles dispersed as positive charges, and an additive liquid containing a polymer including at least one element capable of being activated into a positive charge. A polishing selectivity between a step height removal rate (SHRR) in an oxide film pattern wafer having a convex portion and a concave portion and a blanket wafer removal rate (BWRR) in an oxide film blanket wafer may be greater than or equal to “5:1.” In the present disclosure, the SHRR may refer to a step height region removal rate.

The polymer may inhibit a polishing speed of a low-step height region and may also increase a polishing speed of a convex portion. When a trench is formed through an etching process to form a pattern on a flat surface and when a deposition process of an insulating film (for example, SiO₂) is performed on the trench, a portion having a groove and a portion that does not have a groove may be different in height from each other. Such a height difference is referred to as a “step height.” The step height may be in a range of 500 Å to 10,000 Å based on a depth of the trench by the etching process. A relatively high portion and a relatively low portion based on the height difference may be referred to as a “convex portion (that is, a high-step height region)” and a concave portion (that is, a low-step height region)”, respectively. Using the slurry composition, it is possible to realize a flat surface by removing the above step height.

A selectivity between a removal rate of the convex portion and a removal rate of the concave portion in the oxide film pattern wafer may be greater than or equal to “5:1.” During initial polishing, the convex portion is quickly polished because a physical pressure is strongly applied to the convex portion. Polishing of the concave portion to which a pressure is less applied may be inhibited by protecting the concave portion through a passivation by forming a coating film on a surface of a film using the slurry composition adsorbed onto a polished film. Thus, a polishing stop function may be implemented. When polishing continues to be performed, a step height between the convex portion and the concave portion may be reduced and eliminated, thereby increasing a step height removal efficiency. Therefore, it is possible to efficiently remove a high-step height region due to a denser pattern when an interlayer insulating film is polished, and possible to enhance an uniformity and a yield in a wafer after a planarization.

The metal oxide abrasive particles may include at least one selected from the group of metal oxide, inorganic particles that modifies a surface of the metal oxide, and the metal oxide in a colloidal phase. The metal oxide may include at least one selected from the group consisting of silica, ceria, zirconia, alumina, titania, barium titania, germania, mangania and magnesia.

The metal oxide abrasive particles may be ceria in a colloidal phase dispersed as positive charges.

The metal oxide abrasive particles may be prepared by a liquid-phase method. The liquid-phase method may include, for example, a sol-gel method of subjecting an abrasive particle precursor to a chemical reaction in an aqueous solution and growing crystals to obtain fine particles, a coprecipitation method of precipitating abrasive particle ions in an aqueous solution, and a hydrothermal synthesis method of forming abrasive particles under a high temperature and a high pressure, to prepare the metal oxide abrasive particles. A polishing slurry composition including abrasive particles prepared by the liquid-phase method may reduce micro-scratches occurring in a polishing process due to a shape of a particle similar to a spherical shape, and may have a profile of a uniform polishing speed in a wafer polishing process due to a monodisperse particle-size distribution.

For example, when a slurry composition for polishing a high-step height region, including an additive liquid containing a polymer including at least one element capable of being activated into a positive charge, and a polishing liquid containing metal oxide abrasive particles prepared by the liquid-phase method and dispersed as positive charges, is used to perform a polishing process, a performance of polishing a high-step height region may be implemented and a loading effect may be increased with an excellent planarization efficiency, uniformity and polishing speed. By realizing a homogeneous loading effect, defects and scratches may be reduced.

The metal oxide abrasive particles may be present in an amount of 0.1% by weight (wt to 10 wt % in the slurry composition. When the amount of the metal oxide abrasive particles is less than 0.1 wt %, the polishing speed may decrease. When the amount of the metal oxide abrasive particles is greater than 10 wt %, defects caused by abrasive particles may occur.

The metal oxide abrasive particles may have a size of 10 nm to 100 nm. An average size of primary particles in the slurry composition needs to be less than or equal to 100 nm to ensure a particle uniformity and to reduce scratches and defects. When the average size is less than 10 nm, a polishing rate may decrease so that a desired polishing rate may not be satisfied. Also, abrasive particles according to example embodiments may be used by mixing particles having different sizes to adjust a polishing rate and to reduce dishing and erosion.

The metal oxide abrasive particles may be ceria in a colloidal phase dispersed as positive charges. The ceria in the colloidal phase dispersed as positive charges may be mixed with an additive liquid activated as a positive charge, to realize a higher step height removal performance and an automatic polishing stop function.

The polymer may include at least one nitrogen activated as a positive charge.

The polymer may be in a form of a quaternary ammonium, or a quaternary ammonium salt.

The polymer may include at least one selected from the group consisting of poly(diallyldimethyl ammonium chloride); poly[bis(2-chloroethyl) ether-alt-1,3-bis[3-(dimethylamino)propyl]urea]; ethanol, 2,2′,2″-nitrilotris-, polymer with 1,4-dichloro-2-butene and N,N,N′,N′-tetramethyl-2-butene-1,4-diamine; a hydroxyethyl cellulose dimethyl diallylammonium chloride copolymer; a copolymer of acrylamide and diallyldimethylammonium chloride; a copolymer of acrylamide and quaternized dimethylammoniumethyl methacrylate; a copolymer of acrylic acid and diallyldimethylammonium chloride; an acrylamide-dimethylaminoethyl methacrylate methyl chloride copolymer; quaternized hydroxyethyl cellulose; a copolymer of vinylpyrrolidone and quaternized dimethylaminoethyl methacrylate; a copolymer of vinylpyrrolidone and quaternized vinylimidazole; a copolymer of vinylpyrrolidone and methacrylamidopropyl trimethylammonium; poly(2-methacryloxyethyltrimethylammonium chloride); poly(acrylamide 2-methacryloxyethyltrimethyl ammonium chloride); poly[2-(dimethylamino)ethyl methacrylate) methyl chloride]; poly[(3-acrylamidopropyl) trimethylammonium chloride]; poly[(3-methacrylamidopropyl) trimethylammonium chloride]; poly[oxyethylene(dimethylimino)ethylene (dimethylimino)ethylene dichloride]; a terpolymer of acrylic acid, acrylamide and diallyldimethylammonium chloride; a terpolymer of acrylic acid, methacrylamidopropyl trimethylammonium chloride, and methyl acrylate, a terpolymer of vinylcaprolactam, vinylpyrrolidone, and quaternized vinylimidazole; poly(2-methacryloxyethyl phosphorylcholine-co-n-butyl methacrylate); poly[(dimethylamino)ethyl acrylate benzyl chloride quaternary salt (PDMAEA-BCQ); poly[(dimethylamino)ethyl acrylate methyl chloride quaternary salt (PDMAEA-MCQ); and polymethacrylamidopropyltrimonium chloride.

The polymer including the at least one element capable of being activated into the positive charge may be present in an amount of 0.001 wt % to 0.1 wt % in the slurry composition. When an amount of a polymer including at least one element having cations is less than 0.001 wt %, the automatic polishing stop function may not be implemented. When the amount of the polymer is greater than 0.1 wt %, a step height removal performance may decrease so that a polishing selectivity between a convex portion and a concave portion may not be implemented and a substrate surface defect may increase.

The slurry composition may further include at least one acidic material selected from the group consisting of picolinic acid, polyacrylic acid, a polyacrylic acid-containing copolymer, polysulfonic acid, carboxylic acid, amino acid, acetic acid, malic acid, malonic acid, maleic acid, oxalic acid, phthalic acid, succinic acid, tartaric acid, citric acid, glutaric acid, glycolic acid, formic acid and lactic acid. The polyacrylic acid-containing copolymer may include, for example, a polyacrylic acid-sulfonic acid copolymer, a polyacrylic acid-malonic acid copolymer, and a polyacrylic acid-polystyrene copolymer.

The acidic material may be present in an amount of 0.01 wt % to 1 wt % in the slurry composition. When the amount of the acidic material in the slurry composition is less than 0.01 wt %, the step height removal performance may not be realized. When the amount of the acidic material is greater than 1 wt %, the automatic polishing stop function may be reduced.

The slurry composition may further include a basic material with a pKa value greater than or equal to “9.” The basic material may include at least one selected from the group consisting of arginine, ammonium hydroxide (NH₄OH), propylamine, triethylamine, tributylamine, tetramethylamine, tetramethylammonium hydroxide, monoethanolamine, diethanolamine, triethanolamine, 2-amino-2-ethyl-1,3-propanediol, 2-dimethylamino-2-methyl-1-propanol, 1-amino-2-propanol, 1-dimethylamino-2-propanol, 3-dimethylamino-1-propanol, 2-amino-1-propanol, 2-dimethylamino-1-propanol, 2-diethylamino-1-propanol, 2-diethylamino-1-ethanol, 2-ethylamino-1-ethanol, 1-(dimethylamino)2-propanol, N-methyldiethanolamine, N-propyldiethanolamine, N-isopropyldiethanolamine, N-(2-methylpropyl)diethanolamine, N-n-butyldiethanolamine, N-t-butylethanolamine, N-cyclohexyldiethanolamine, 2-(dimethylamino)ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl)ethanolamine, 2-amino-2-methyl-1-propanol, tris(hydroxymethyl)aminomethane, and triisopropanolamine.

The basic material may be present in an amount of 0.01 wt % to 1 wt % in the slurry composition. When the amount of the basic material in the slurry composition is less than 0.01 wt %, the step height removal performance may be reduced. When the amount of the basic material is greater than 1 wt %, the automatic polishing stop function may be reduced.

The slurry composition may have a pH in a range of 3 to 8. When the pH decreases, a polishing speed may decrease, and when the pH increases, the polishing speed may increase. However, when the pH exceeds 8, the automatic polishing stop function may be rapidly reduced, thereby lowering a performance of removing a high-step height region.

The slurry composition may further include water. The water may include, for example, deionized water, ion exchanged water, and ultrapure water.

A ratio of the polishing liquid:the water:the additive liquid may be in a range of “1:3 to 10:1 to 8.” When a proportion of the additive liquid decreases in a range of 1 to 4, a suitability for use in polishing a bulk high-step height region may increase. When the proportion of the additive liquid increases in a range of 5 to 8, the automatic polishing stop function may be strengthened, thereby effectively removing a remaining step height region during a polishing process.

For example, a slurry composition may be provided in a form of a two-liquid type composition in which a polishing liquid and an additive liquid are separately prepared and are mixed immediately before polishing, or may be provided in a form of a one-liquid type composition in which a polishing liquid and an additive liquid are mixed.

Hereinafter, the present disclosure will be described in detail with reference to examples. However, the following examples are illustrative only, and do not limit the scope of the present disclosure.

### Example 1

250 ppm of polymethacrylamidopropyltrimonium chloride as a polymer, 0.1 wt % of citric acid as an acidic material, and 2-amino-2-ethyl-1,3-propanediol (AEPD) as a basic material were added, and pH was adjusted to 3, followed by mixing, to prepare an additive liquid. Also, a polishing liquid containing 4 wt % of ceria abrasive particles was prepared, and a ratio of the polishing liquid:ultrapure water:the additive liquid was “1:6:4,” to prepare a slurry composition for polishing a high-step height region.

### Example 2

250 ppm of polymethacrylamidopropyltrimonium chloride as a polymer, 0.1 wt % of citric acid as an acidic material, and 2-amino-2-ethyl-1,3-propanediol (AEPD) as a basic material were added, and pH was adjusted to 5, followed by mixing, to prepare an additive liquid. Also, a polishing liquid containing 4 wt % of ceria abrasive particles was prepared, and a ratio of the polishing liquid:ultrapure water:the additive liquid was “1:6:4,” to prepare a slurry composition for polishing a high-step height region.

### Example 3

A slurry composition for polishing a high-step height region was prepared in the same manner as in Example 2, except that 0.05 wt % of picolinic acid as an acidic material was added.

### Example 4

A slurry composition for polishing a high-step height region was prepared in the same manner as in Example 2, except that 0.1 wt % of acetic acid as an acidic material was added.

### Example 5

A slurry composition for polishing a high-step height region was prepared in the same manner as in Example 2, except that 0.1 wt % of malonic acid as an acidic material was added.

### Example 6

A slurry composition for polishing a high-step height region was prepared in the same manner as in Example 2, except that 0.1 wt % of tartaric acid as an acidic material was added.

### Example 7

A slurry composition for polishing a high-step height region was prepared in the same manner as in Example 2, except that 0.1 wt % of polyacrylic acid (PAA) 10K as an acidic material was added.

### Example 8

A slurry composition for polishing a high-step height region was prepared in the same manner as in Example 2, except that 0.1 wt % of citric acid as an acidic material and arginine as a basic material were added.

### Example 9

A slurry composition for polishing a high-step height region was prepared in the same manner as in Example 8, except that 0.1 wt % of tartaric acid as an acidic material was added.

### Example 10

300 ppm of polymethacrylamidopropyltrimonium chloride as a polymer, 0.1 wt % of acetic acid as an acidic material, and arginine as a basic material were added, and pH was adjusted to 5, followed by mixing, to prepare an additive liquid. Also, a polishing liquid containing 4 wt % of ceria abrasive particles was prepared, and a ratio of the polishing liquid:ultrapure water:the additive liquid was “1:6:4,” to prepare a slurry composition for polishing a high-step height region.

### Example 11

A slurry composition for polishing a high-step height region was prepared in the same manner as in Example 10, except that 0.05 wt % of tartaric acid as an acidic material was added.

A wafer in which a concave portion and a convex portion were formed was polished using the slurry compositions prepared according to Examples 1 through 11 under the following polishing conditions.

[Polishing Conditions]

1. Polishing machine: UNIPLA 231 DoosanMecatec 200 mm

2. Wafers: PETEOS 20K (A), ILD Pattern Wafer 15K (A), Trench Depth 10K (A)

3. Platen speed: 24 rpm

4. Spindle speed: 90 rpm

5. Wafer pressure: 4 psi

6. Slurry flow rate: 200 ml/min

Table 1 shows a blanket wafer removal rate (BWRR) and a pattern wafer step height removal rate (SHRR) based on a mixture of the slurry compositions prepared according to Examples 1 through 11.

TABLE 1

| | Additive liquid | | | | | | |
|---|---|---|---|---|---|---|---|
| | | Acidic | | | 200 mm CMP | | |
| | Polymer | material | Basic | | BWRR | SHRR | |
| Classification | (ppm) | (wt %) | material | pH | (Å/min) | (Å/min) | Selectivity |
| Example 1 | 250 | Citric acid | AEPD | 3 | 224 | 1173 | 5.24 |
| | | 0.1 | | | | | |
| Example 2 | 250 | Citric acid | AEPD | 5 | 355 | 2733 | 7.70 |
| | | 0.1 | | | | | |
| Example 3 | 250 | Picolinic acid | AEPD | 5 | 64 | 783 | 12.23 |
| | | 0.05 | | | | | |
| Example 4 | 250 | Acetic acid | AEPD | 5 | 974 | 5141 | 5.28 |
| | | 0.1 | | | | | |
| Example 5 | 250 | Malonic acid | AEPD | 5 | 895 | 5770 | 6.45 |
| | | 0.1 | | | | | |
| Example 6 | 250 | Tartaric acid | AEPD | 5 | 460 | 3407 | 7.41 |
| | | 0.1 | | | | | |
| Example 7 | 250 | Polyacrylic | AEPD | 5 | 413 | 2779 | 6.73 |
| | | acid (10K) | | | | | |
| | | 0.1 | | | | | |
| Example 8 | 250 | Citric acid | Arginine | 5 | 427 | 2565 | 6.01 |
| | | 0.1 | | | | | |
| Example 9 | 250 | Tartaric acid | Arginine | 5 | 331 | 2750 | 8.31 |
| | | 0.1 | | | | | |
| Example 10 | 300 | Acetic acid | Arginine | 5 | 99 | 3782 | 38.20 |
| | | 0.1 | | | | | |
| Example 11 | 300 | Tartaric acid | Arginine | 5 | 273 | 2883 | 10.56 |
| | | 0.05 | | | | | |

It is found that a polishing selectivity between an SHRR in an oxide film pattern wafer having a convex portion and a concave portion and a blanket wafer removal rate (BWRR) in an oxide film blanket wafer is greater than or equal to “5:1” when the slurry compositions prepared according to Examples 1 to 11 are used. Thus, it may be confirmed that a step height removal performance is significantly excellent because the convex portion is polished at a relatively high polishing speed and a polishing stop function is strengthened in the concave portion.

Although a few embodiments of the present disclosure have been shown and described, the present disclosure is not limited to the described embodiments. Instead, it would be appreciated by those skilled in the art that changes may be made to these embodiments without departing from the principles and spirit of the present disclosure, the scope of which is defined by the claims and their equivalents.

What is claimed is:

1. A slurry composition for polishing a high-step height region, the slurry composition comprising:
a polishing liquid containing metal oxide abrasive particles dispersed as positive charges; and
an additive liquid containing a polymer comprising at least one element capable of being activated into a positive charge,
wherein a polishing selectivity between a step height removal rate (SHRR) in an oxide film pattern wafer having a convex portion and a concave portion and a blanket wafer removal rate (BWRR) in an oxide film blanket wafer is greater than or equal to “5:1.”

2. The slurry composition of claim 1, wherein a selectivity between a removal rate of the convex portion and a removal rate of the concave portion in the oxide film pattern wafer is greater than or equal to “5:1.”

3. The slurry composition of claim 1, wherein
the metal oxide abrasive particles comprise at least one selected from the group consisting of a metal oxide, a metal oxide coated with an organic material or inorganic material, and the metal oxide in a colloidal phase, and
the metal oxide comprises at least one selected from the group consisting of silica, ceria, zirconia, alumina, titania, barium titania, germania, mangania and magnesia.

4. The slurry composition of claim 1, wherein the metal oxide abrasive particles are ceria in a colloidal phase dispersed as positive charges.

5. The slurry composition of claim 1, wherein the polymer comprises at least one nitrogen activated as a positive charge.

6. The slurry composition of claim 1, wherein the polymer is in a form of a quaternary ammonium, or a quaternary ammonium salt.

7. The slurry composition of claim 1, wherein the polymer comprises at least one selected from the group consisting of:
poly(diallyldimethyl ammonium chloride);
poly[bis(2-chloroethyl) ether-alt-1,3-bis[3-(dimethylamino)propyl]urea];
ethanol, 2,2′,2″-nitrilotris-, polymer with 1,4-dichloro-2-butene and N,N,N′,N′-tetramethyl-2-butene-1,4-diamine;
a hydroxyethyl cellulose dimethyl diallylammonium chloride copolymer;
a copolymer of acrylamide and diallyldimethylammonium chloride;
a copolymer of acrylamide and quaternized dimethylammoniumethyl methacrylate;
a copolymer of acrylic acid and diallyldimethylammonium chloride;
an acrylamide-dimethylaminoethyl methacrylate methyl chloride copolymer;
quaternized hydroxyethyl cellulose;
a copolymer of vinylpyrrolidone and quaternized dimethylaminoethyl methacrylate;
a copolymer of vinylpyrrolidone and quaternized vinylimidazole;
a copolymer of vinylpyrrolidone and methacrylamidopropyl trimethylammonium;
poly(2-methacryloxyethyltrimethylammonium chloride);
poly(acrylamide 2-methacryloxyethyltrimethyl ammonium chloride);
poly[2-(dimethylamino)ethyl methacrylate) methyl chloride];
poly[(3-acrylamidopropyl) trimethylammonium chloride];
poly[(3-methacrylamidopropyl) trimethylammonium chloride];
poly[oxyethylene(dimethylimino)ethylene (dimethylimino)ethylene dichloride];
a terpolymer of acrylic acid, acrylamide and diallyldimethylammonium chloride;
a terpolymer of acrylic acid, methacrylamidopropyl trimethylammonium chloride, and methyl acrylate, a terpolymer of vinylcaprolactam, vinylpyrrolidone, and quaternized vinylimidazole;
poly(2-methacryloxyethyl phosphorylcholine-co-n-butyl methacrylate);
poly[(dimethylamino)ethyl acrylate benzyl chloride quaternary salt (PDMAEA-BCQ);
poly[(dimethylamino)ethyl acrylate methyl chloride quaternary salt (PDMAEA-MCQ); and
polymethacrylamidopropyltrimonium chloride.

8. The slurry composition of claim 1, wherein the polymer comprising at least one element capable of being activated into a positive charge is present in an amount of 0.001% by weight (wt %) to 0.1 wt % in the slurry composition.

9. The slurry composition of claim 1, further comprising:
at least one acidic material selected from the group consisting of picolinic acid, polyacrylic acid, a polyacrylic acid-containing copolymer, polysulfonic acid, carboxylic acid, amino acid, acetic acid, malic acid, malonic acid, maleic acid, oxalic acid, phthalic acid, succinic acid, tartaric acid, citric acid, glutaric acid, glycolic acid, formic acid and lactic acid.

10. The slurry composition of claim 1, further comprising:
a basic material with a pKa value greater than or equal to “9.”

11. The slurry composition of claim 10, wherein the basic material comprises at least one selected from the group consisting of arginine, ammonium hydroxide (NH₄OH), propylamine, triethylamine, tributylamine, tetramethylamine, tetramethylammonium hydroxide, monoethanolamine, diethanolamine, triethanolamine, 2-amino-2-ethyl-1,3-propanediol, 2-dimethylamino-2-methyl-1-propanol, 1-amino-2-propanol, 1-dimethylamino-2-propanol, 3-dimethylamino-1-propanol, 2-amino-1-propanol, 2-dimethylamino-1-propanol, 2-diethylamino-1-propanol, 2-diethylamino-1-ethanol, 2-ethylamino-1-ethanol, 1-(dimethylamino)2-propanol, N-methyldiethanolamine, N-propyldiethanolamine, N-isopropyldiethanolamine, N-(2-methylpropyl)diethanolamine, N-n-butyldiethanolamine, N-t-butylethanolamine, N-cyclohexyldiethanolamine, 2-(dimethyl amino) ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl)ethanolamine, 2-amino-2-methyl-1-propanol, tris(hydroxymethyl)aminomethane, and triisopropanolamine.

12. The slurry composition of claim 1, wherein the slurry composition has a pH in a range of 3 to 8.

13. The slurry composition of claim 1, further comprising:
water,
wherein a ratio of the polishing liquid:the water:the additive liquid is in a range of “1:3 to 10:1 to 8.”
